(19) United States
(12) Patent Application Publication
(10) Pub. No.: US 2007/0263352 A1
(43) Pub. Date: Nov. 15, 2007

(54) Plastics Utilizing Thermally Conductive Film

(75) Inventors: Kinzy Jones, Hollywood, FL (US); Christopher J. Bates, Hollywood, FL (US); Brian B. Belknap, Davie, FL (US); Emory D. Carroll, Boynton Beach, FL (US)

Correspondence Address: CUENOT & FORSYTHE, L.L.C., 12230 FOREST HILL BLVD., SUITE 120, WELLINGTON, FL, 33414, US

(73) Assignee: Motorola, Inc., Schaumburg, IL (US)

(21) Appl. No.: 11/383,427

(22) Filed: May 15, 2006

(51) Int. Cl. H05K 7/20

(52) U.S. Cl. 361/688

(57) ABSTRACT

A device housing (105) and a method (500) of manufacturing the same. The method can include positioning within a mold (300) an insert (205) of thermally conductive film (210). For example, graphite film can be positioned within the mold. The graphite film can have a first thermal conductivity in an in-plane direction (215) and a second thermal conductivity in a normal direction (220) that is less than one-tenth the first thermal conductivity. For example, the graphite film can have a first thermal conductivity in an in-plane direction that is greater than about 150 W/m-K and a second thermal conductivity in a normal direction that is less than 15 W/m-K. An electronic circuit (400) including at least one thermal energy generator (405) can be positioned into the device housing. The thermal energy generator can be positioned proximate to the insert of thermally conductive film.

### BACKGROUND OF THE INVENTION

1. Field of the Invention

The present invention generally relates to plastics and, more particularly, to plastic enclosures.

2. Background of the Invention

In general, plastic materials are fairly inexpensive, yet very versatile for use in manufacturing. Consequently, since around the middle of the twentieth century, the use of plastics in manufacturing has grown significantly. Indeed, plastic is now the most used manufacturing material in the world and products which include plastic are a common part of present day life. One of the many industries that have embraced the use of plastic is the electronics industry. Various plastic materials now are used to form a myriad of electronic device components, for example printed circuit boards, enclosures for electronic circuits and electrical insulators.

Electronic circuits tend to generate thermal energy (i.e. heat) during operation, mostly due to power losses in electronic components. In comparison to other materials, such as metal, plastic typically is not a very good thermal conductor. Thus, plastic is not very effective at conducting thermal energy away from electronic components. As a result, undesirable hot spots tend to form in regions immediately surrounding the electrical components that generate the greatest amount of thermal energy. It therefore would be desirable to reduce the temperature at those hotspots, while still using inexpensive and versatile manufacturing materials.

### SUMMARY OF THE INVENTION

The present invention relates to a method of manufacturing a device housing. The method can include positioning within a mold an insert of thermally conductive film. For example, graphite film can be positioned within the mold. The graphite film can have a first thermal conductivity in an in-plane direction and a second thermal conductivity in a normal direction that is less than one-tenth the first thermal conductivity. For example, the graphite film can have a first thermal conductivity in the in-plane direction that is greater than about 150 W/m-K and a second thermal conductivity in the normal direction that is less than 15 W/m-K.

The method also can include injecting plastic within the mold such that when the plastic is set into its molded shape to form at least a first portion of the device housing, the plastic is bonded to the insert of thermally conductive film. When the plastic is set into its molded shape, the first portion of the device housing can include a surface having a first amount of surface area that is no greater than three times a second amount of surface area of a surface of the insert of thermally conductive film.

An electronic circuit including at least one thermal energy generator can be positioned into the device housing. The thermal energy generator can be positioned proximate to the insert of thermally conductive film.

The present invention also relates to a device housing that includes a first housing portion. The first housing portion can include an insert of thermally conductive film and a plastic housing member. The insert of thermally conductive film can include a graphite film. The insert of thermally conductive film can be bonded to the plastic housing member during a molding process in which the plastic housing member is set into its molded shape. The insert of thermally conductive film can include a first surface having a first amount of surface area. The plastic housing member can include a second surface having a second amount of surface area that is no greater than three times the first amount of surface area.

A first thermal conductivity of the insert of thermally conductive film in an in-plane direction can be at least ten times a second thermal conductivity of the insert of thermally conductive film in a normal direction. For example, the first thermal conductivity of the insert of thermally conductive film in an in-plane direction can be greater than about 150 W/m-K and a second thermal conductivity of the insert of thermally conductive film in a normal direction can be less than 15 W/m-K.

### BRIEF DESCRIPTION OF THE DRAWINGS

Preferred embodiments of the present invention will be described below in more detail, with reference to the accompanying drawings, in which:

FIG. 1 depicts a perspective view of a device that is useful for understanding the present invention;

FIG. 2 depicts a perspective view of a portion of a device housing that is useful for understanding the present invention;

FIG. 3 depicts a perspective view of a plastics mold that is useful for understanding the present invention;

FIG. 4 depicts an enlarged section view of the device of FIG. 1 taken along section line 4-4; and

FIG. 5 is flowchart that is useful for understanding a process for molding an insert of thermally conductive film into a portion of a device housing.

### DETAILED DESCRIPTION

While the specification concludes with claims defining features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

The present invention relates to a device housing that, while being molded substantially from plastic, is thermally conductive. More particularly, the device housing can include a first housing portion that is bonded to an insert of thermally conductive film during the molding process. The thermally conductive film can be, for example, a graphite film which has a thermal conductivity in an in-plane direction (i.e. parallel to the planar surface of the film) that is significantly higher than its thermal conductivity an a normal direction (i.e. normal to the planar surface of the film). Accordingly, thermal energy generated near a particular portion of the insert can be efficiently spread across the entire surface of the insert and then uniformly transferred to the environment.

Transferring the thermal energy in this manner reduces the maximum temperature of hot spots on the device housing and results in a uniform temperature distribution across the housing surface. The uniform temperature distribution improves user comfort while holding mobile devices, such as laptop computers, mobile telephones and personal digital assistants (PDAs). Moreover, reducing the maximum temperature of hot spots reduces the temperature of devices proximately located thereto, thereby extending the operating life of such devices.

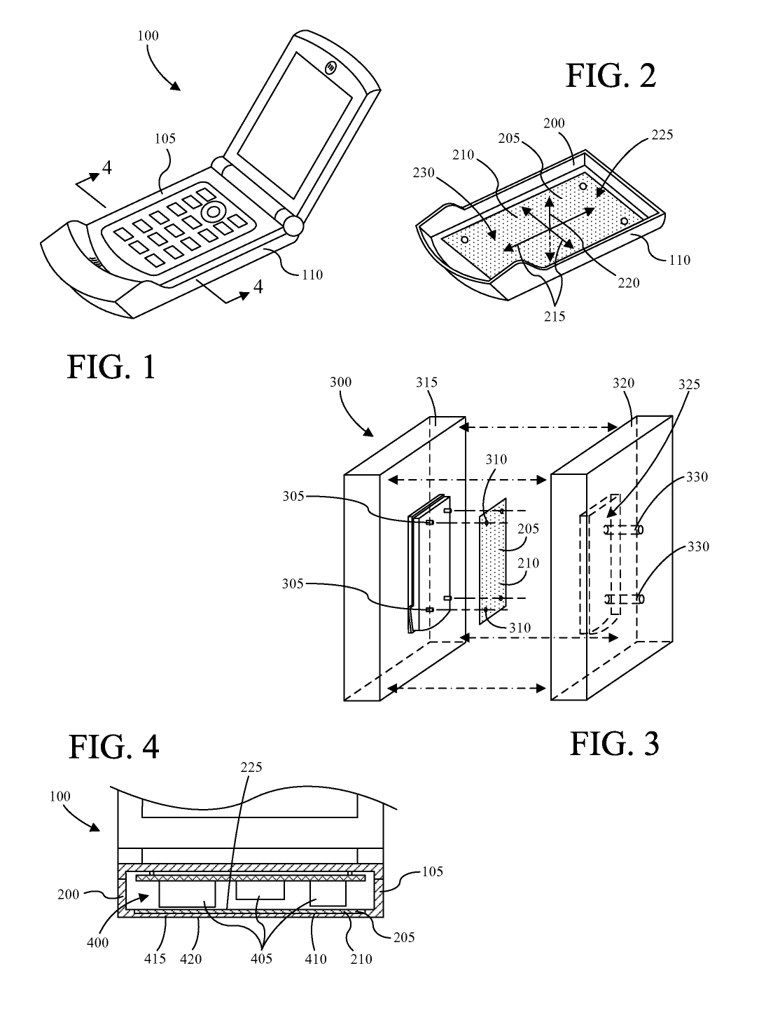

FIG. 1 depicts a device 100 having a device housing 105 that is useful for understanding the present invention. The device can be an electronic device, for example a telephone, a mobile telephone, a personal digital assistant, a computer, a television, audio equipment, automotive equipment, aerospace equipment, etc. The device housing 105 can include at least a first housing portion 110 that is molded of plastic. Examples of plastic materials that can be used to mold the first housing portion 110 include LEXAN® resin and THERMOCOMP® resin, both of which are available from the GE Advanced Materials division of the General Electric Company, which is currently located in Pittsfield, Mass. Another suitable plastic material is glass filled nylon. Still, a myriad of other plastic materials can be used and the invention is not limited in this regard.

FIG. 2 depicts a perspective view of the first portion 110 of the device housing 105. In accordance with the inventive arrangements described herein, the first housing portion 110 can include a first housing member 200 that is bonded to an insert 205 of thermally conductive film 210. The thermally conductive film 210 can be, for instance, a graphite film having a thickness anywhere from about 0.08 mm to about 1.52 mm. Graphite film can exhibit very high thermal conductivity in a direction 215 that is parallel to a plane defined by the graphite film (i.e. “in-plane direction”), yet fairly low thermal conductivity in a direction 220 that is normal to the plane (i.e. “normal direction”). Accordingly, the thermal conductivity in the in-plane directions 215 can be much greater than the thermal conductivity in the normal direction 220. One example of a commercially available graphite film that can be used as the thermally conductive film 210 is zSPREADER™ natural graphite heat spreader available from Graffech Advanced Energy Technology Inc. of Cleveland, Ohio.

In one arrangement, the thermal conductivity in the in-plane directions 215 can be greater than about 150 W/m-K while the thermal conductivity in the normal direction 220 is less than about 15 W/m-K. Thus, the thermal conductivity in the in-plane directions 215 can be greater than ten times the thermal conductivity in the normal direction 220. In another arrangement, the thermal conductivity in the in-plane directions 215 can be greater than 600 W/m-K while the thermal conductivity in the normal direction 220 is less than 6 W/m-K. This represents a ratio between the thermal conductivity in the in-plane directions 215 and the thermal conductivity in the normal direction 220 that is greater than one hundred to one. Still, greater in-plane thermal conductivities and lower thermal conductivities in the normal direction can be achieved and the invention is not limited to these examples.

The effectiveness of the insert 205 at dissipating heat from a particular hot spot can be roughly proportional to a surface area of the insert 205. Thus, in general, a larger insert 205 should provide better heat dissipation than a smaller insert. In that regard, the insert 205 can have a surface 225 which has a surface area that is at least equal to a substantial portion of a surface area of the housing surface 230. For example, the insert 205 can define at least one-third of the total area of the housing surface 230.

The insert 205 can be cut from a larger sheet of the thermally conductive film 210. The thermally conductive film 210 can be semi-rigid or pliable. In an arrangement in which the thermally conductive film 210 is semi-rigid, the insert 205 can be formed into a desired shape using known stamping techniques. In an arrangement in which the thermally conductive film 210 is pliable, the insert 205 can form to the shape of a mold to which it is inserted during the molding process.

FIG. 3 depicts a perspective view of a plastics mold 300 that is useful for understanding the present invention. Prior to injecting plastic into the mold 300 during the molding process, the insert 205 can be robotically positioned within the mold 300 and mechanically held in an appropriate position. For instance, either the insert 205 or the injection mold 300 can include features that hold the insert 205 in place within the mold 300. By way of example, the mold can include protrusions 305 that engage holes 310 defined within the insert 205. Notwithstanding, the invention is not limited in this regard and any other suitable mold 300 and/or insert 205 features can be implemented.

After the insert 205 has been inserted into the mold 300 and secured into place, mold plates 315, 320 can be pressed together to substantially enclose a cavity 325 in which the insert 205 is contained. Plastic then can be injected through one or more channels 330 to fill the cavity 325 with plastic. As noted, the invention is not limited to the type of plastic that can be used. When the plastic sets into its molded shape, the plastic can be bonded to the insert 205 of thermally conductive film 210 to form the portion 110 of the device housing depicted in FIG. 2. The portion 110 of the device housing then can be assembled with other housing portions to form the housing 105 of the device 100 shown in FIG. 1.

FIG. 4 depicts a section view of the device 100 of FIG. 1 taken along section line 4-4. The insert 205 of thermally conductive material 210 can be integrated into the housing portion 110 during the molding process such that when the device 100 is assembled, the insert 205 is positioned proximate to one or more device components 405 of an electronic circuit 400. The device components 405 may generate thermal energy. The insert 205 can evenly spread such thermal energy across its planar surfaces 225, 410 and evenly transfer the thermal energy through a region 415 of the housing member 200 to which the insert 205 is bonded. Because the thermally energy is evenly transferred, temperature fluctuations across a surface of the 420 of the device housing 105 can be minimized.

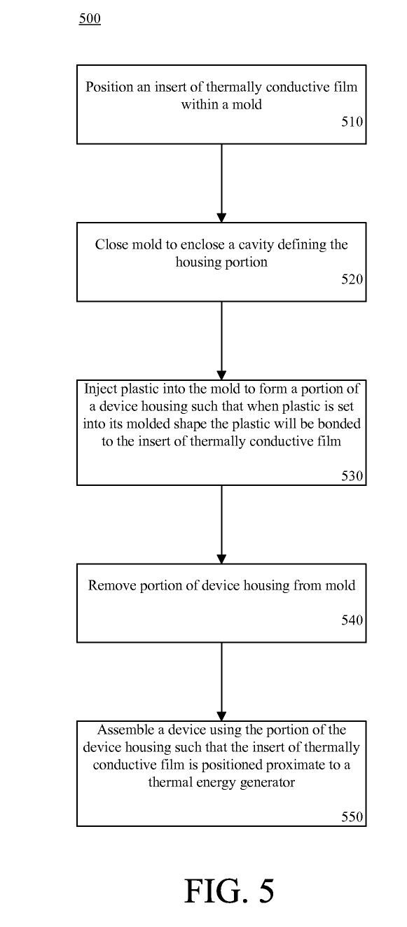

FIG. 5 is flowchart that is useful for understanding a process 500 for molding an insert of thermally conductive film into a portion of a device housing. At step 510, the insert can be positioned within a mold. For example, the insert can be robotically positioned and secured using features in the mold and/or features defined in the insert. At step 520 the mold can be closed to enclose a cavity defining the housing portion. Proceeding to step 530, plastic can be injected into the mold to form a portion of a device housing such that when the plastic is set into its molded shape the plastic will be bonded to the insert of thermally conductive film. Continuing to step 540, the portion of the device housing can be removed from the mold. At step 550 a device can be assembled using the portion of the device housing such that the insert of thermally conductive film is positioned proximate to a thermal energy generator.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language).

This invention can be embodied in other forms without departing from the spirit or essential attributes thereof. Accordingly, reference should be made to the following claims, rather than to the foregoing specification, as indicating the scope of the invention.

What is claimed is:

1. A method of manufacturing a device housing, comprising:
positioning within a mold an insert of thermally conductive film; and
injecting plastic within the mold such that when the plastic is set into its molded shape to form at least a first portion of the device housing, the plastic is bonded to the insert of thermally conductive film.

2. The method of claim 1, wherein injecting plastic within the mold comprises injecting the plastic such that when the plastic is set into its molded shape, the first portion of the device housing comprises a surface having a first amount of surface area that is no greater than three times a second amount of surface area of a surface of the insert of thermally conductive film.

3. The method of claim 1, wherein positioning within the mold the insert of thermally conductive film comprises positioning a graphite film within the mold.

4. The method of claim 1, wherein positioning within the mold the insert of thermally conductive film comprises positioning within the mold a graphite film having a first thermal conductivity in an in-plane direction and a second thermal conductivity in a normal direction that is less than one-tenth the first thermal conductivity.

5. The method of claim 1, wherein positioning within the mold the insert of thermally conductive film comprises positioning within the mold a graphite film having a first thermal conductivity in an in-plane direction that is greater than about 150 W/m-K.

6. The method of claim 1, wherein positioning within the mold the insert of thermally conductive film comprises positioning within the mold a graphite film having a first thermal conductivity in an in-plane direction that is greater than about 150 W/m-K and a second thermal conductivity in a normal direction that is less than 15 W/m-K.

7. A method of manufacturing an electronic device, comprising:
positioning within a mold an insert of thermally conductive film; and
injecting plastic within the mold such that when the plastic is set into its molded shape to form at least a first portion of a device housing the plastic is bonded to the insert of thermally conductive film; and
positioning an electronic circuit comprising at least one thermal energy generator into the device housing.

8. The method of claim 7, wherein positioning the electronic circuit comprises positioning the thermal energy generator proximate to the insert of thermally conductive film.

9. The method of claim 7, wherein injecting plastic within the mold comprises injecting the plastic such that when the plastic is set into its molded shape, the first portion of the device housing comprises a surface having a first amount of surface area that is no greater than three times a second amount of surface area of a surface of the insert of thermally conductive film.

10. The method of claim 7, wherein positioning within the mold the insert of thermally conductive film comprises positioning within the mold a graphite film having a first thermal conductivity in an in-plane direction and a second thermal conductivity in a normal direction that is less than one-tenth the first thermal conductivity.

11. The method of claim 7, wherein positioning within the mold the insert of thermally conductive film comprises positioning within the mold a graphite film having a first thermal conductivity in an in-plane direction that is greater than about 150 W/m-K.

12. The method of claim 7, wherein positioning within the mold the insert of thermally conductive film comprises positioning within the mold a graphite film having a first thermal conductivity in an in-plane direction that is greater than about 150 W/m-K and a second thermal conductivity in a normal direction that is less than 15 W/m-K.

13. A device housing comprising:
a first housing portion comprising:
an insert of thermally conductive film; and
a plastic housing member;
wherein the insert of thermally conductive film is bonded to the plastic housing member during a molding process in which the plastic housing member is set into its molded shape.

14. The device housing of claim 13, wherein:
the insert of thermally conductive film comprises a first surface having a first amount of surface area; and
the plastic housing member comprises a second surface having a second amount of surface area that is no greater than three times the first amount of surface area.

15. The device housing of claim 13, wherein the insert of thermally conductive film comprises a graphite film.

16. The device housing of claim 13, wherein a first thermal conductivity of the insert of thermally conductive film in an in-plane direction is at least ten times a second thermal conductivity of the insert of thermally conductive film in a normal direction.

17. The device housing of claim 13, wherein a first thermal conductivity of the insert of thermally conductive film in an in-plane direction is greater than about 150 W/m-K.

18. The device housing of claim 13, wherein a first thermal conductivity of the insert of thermally conductive film in an in-plane direction is greater than about 150 W/m-K and a second thermal conductivity of the insert of thermally conductive film in a normal direction that is less than 15 W/m-K.

19. The device housing of claim 13, further comprising an electronic circuit positioned within the device housing.

20. The device housing of claim 13, wherein the electronic circuit comprises at least one thermal energy generator, the thermal energy generator positioned proximate to the insert of thermally conductive film.
